(19) United States
(12) Patent Application Publication
(10) Pub. No.: US 2024/0329147 A1
(43) Pub. Date: Oct. 3, 2024

(54) Method and device for evaluating the battery consistency based on in-situ electrochemical impedance spectroscopy

(71) Applicant: HEFEI UNIVERSITY, Hefei (CN)

(72) Inventors: Xulai YANG, Hefei (CN); Wenjing YANG, Hefei (CN); Xinling YU, Hefei (CN)

(73) Assignee: HEFEI UNIVERSITY, Hefei (CN)

(21) Appl. No.: 18/619,271

(22) Filed: Mar. 28, 2024

(30) Foreign Application Priority Data
Mar. 28, 2023 (CN) 202310314779.3

(51) Int. Cl. G01R 31/389; G01R 31/3835; G01R 31/396; H01M 10/48; H01M 50/512

(52) U.S. Cl. CPC G01R 31/389; G01R 31/3835; G01R 31/396; H01M 10/482; H01M 50/512

(57) ABSTRACT

The present disclosure provides a method and device for detecting the consistency of connection points of a battery pack. The battery pack includes a plurality of cells or a plurality of parallel battery modules, and the connection points are arranged among the plurality of cells or the plurality of parallel battery modules. The method is based on an electrochemical workstation with auxiliary voltage measurements, and includes the following steps: simultaneously detecting AC impedance spectra of the plurality of cells or the plurality of parallel battery modules through the auxiliary voltage measurements on the basis that the electrochemical workstation applies AC signals with different frequencies and specific amplitudes to the battery pack; and comparing corresponding ohmic impedances and charge transfer impedances in the AC impedance spectra of the plurality of cells or the plurality of parallel battery modules to determine the consistency of the battery pack.

### TECHNICAL FIELD

The present disclosure relates to the field of batteries, in particular to a method and device for detecting the consistency of a battery pack.

### BACKGROUND

Lithium-ion battery cells need to be connected in series and parallel to meet the use requirements of new energy vehicles, etc. This process involves the consistency of the cells and the reliability of series-parallel electrical connection. Lithium-ion battery cells generally need to be put into the production process of battery pack after consistency sorting and grouping, and the sorting parameters are mainly internal resistance, capacity and voltage, etc. Some enterprises with strong manufacturing ability will strictly control the manufacturing process, so the manufactured cell products have high consistency, and can directly enter the manufacturing process of battery pack without sorting. Recently, it has been found that the negative influence of reliability problems such as cold solder of external connection points of the cells on the battery pack is far greater than the difference of internal resistance or capacity of the cells, and then the reliability of electrical connection of the battery pack is particularly important on the basis of the consistency of the cells. Tests for the reliability of the electrical connection of the cells include screw torque verification, half-break detection with tool pry, X-ray transmission imaging detection, and thermal imaging detection.

In the process of AC impedance spectrum detection, a single detection channel of the conventional electrochemical workstation can only detect the electrochemical impedance characteristics of one cell or one battery pack at a time, and the multi-channel electrochemical workstation can only measure a plurality of independent cells or battery packs at the same time. This method can be used to evaluate the consistency between different cells or different battery packs. But in fact, the consistency of a battery pack is not only affected by the consistency of single cells, but also affected by factors such as the impedance of connection points. However, in the process of measuring the AC impedance of a battery pack by a traditional electrochemical workstation, it is difficult to clarify the reasons for the inconsistency induced inside the battery pack.

### SUMMARY

An object of embodiments of the present disclosure is to provide a method and device for detecting the consistency of a battery pack. The method and device for detecting the consistency of a battery pack can detect and analyze the consistency of cells and connection points in the battery pack, and have the characteristics of no damage and rapidness.

In order to achieve the above object, an embodiment of the present disclosure provides a method for detecting the consistency of a battery pack, wherein the battery pack includes a plurality of cells or a plurality of parallel battery modules, and connection points are arranged among the plurality of cells or the plurality of parallel battery modules. The method is based on an electrochemical workstation with auxiliary voltage measurements, and includes the following steps: simultaneously detecting AC impedance spectra of the plurality of cells or the plurality of parallel battery modules through the auxiliary voltage measurements on the basis that the electrochemical workstation applies AC signals with different frequencies and specific amplitudes to the battery pack; and comparing corresponding ohmic impedances and charge transfer impedances in the AC impedance spectra of the plurality of cells or the plurality of parallel battery modules to determine the consistency of the battery pack.

Preferably, comparing corresponding ohmic impedances and charge transfer impedances in the AC impedance spectra of the plurality of cells or the plurality of parallel battery modules to determine the consistency of the battery pack includes: determining that the consistency of the battery pack is normal when the ohmic impedances and the charge transfer impedances in all AC impedance spectra of the plurality of cells or the plurality of parallel battery modules all satisfy a preset condition, wherein the preset condition is that a difference in the charge transfer impedances is smaller than a first threshold and a difference in the ohmic impedances is smaller than a second threshold under the same AC signal.

Preferably, comparing corresponding ohmic impedances and charge transfer impedances in the AC impedance spectra of the plurality of cells or the plurality of parallel battery modules to determine the consistency of the battery pack includes: determining that the consistency of the battery pack is abnormal when the ohmic impedances and the charge transfer impedances in any AC impedance spectrum and other AC impedance spectra of the plurality of cells or the plurality of parallel battery modules do not satisfy a preset condition, wherein the preset condition is that a difference in the charge transfer impedances is smaller than a first threshold and a difference in the ohmic impedances is smaller than a second threshold under the same AC signal.

Preferably, when it is determined that the consistency of the battery pack is abnormal, and the battery pack is a parallel battery pack, the method further includes: determining that a cell corresponding to an AC impedance spectrum with a greater ohmic impedance and the difference greater than the second threshold and the difference in the charge transfer impedances smaller than the first threshold compared with other AC impedance spectra is an abnormal cell.

Preferably, when it is determined that the consistency of the battery pack is abnormal, and the battery pack is a parallel battery pack, the method further includes: determining that a connection point between a cell corresponding to an AC impedance spectrum with a smaller ohmic impedance and the difference greater than the second threshold and a smaller charge transfer impedance and the difference greater than the first threshold compared with other AC impedance spectra, and a cell adjacent to the cell and away from the positive terminal or negative terminal of the battery pack is an abnormal connection point.

Preferably, when it is determined that the consistency of the battery pack is abnormal, and the battery pack is a series battery pack or a plurality of parallel battery modules connected in series, the method further includes: determining that a connection point between a cell or parallel battery module corresponding to an AC impedance spectrum with a greater ohmic impedance and the difference greater than the second threshold and the difference in the charge transfer impedances smaller than the first threshold compared with other AC impedance spectra, and a cell or parallel battery module adjacent to the cell or parallel battery module and away from the positive terminal or negative terminal of the battery pack is an abnormal connection point.

An embodiment of the present disclosure further provides a device for detecting the consistency of a battery pack, the battery pack includes a plurality of cells or a plurality of parallel battery modules, and connection points are arranged among the plurality of cells or the plurality of parallel battery modules. The device is based on an electrochemical workstation with auxiliary voltage measurements, and includes a processor, wherein the processor is configured to execute the following program modules stored in a memory: a detection unit, configured to simultaneously detect AC impedance spectra of the plurality of cells or the plurality of parallel battery modules through the auxiliary voltage measurements on the basis that the electrochemical workstation applies AC signals with different frequencies and specific amplitudes to the battery pack; and a processing unit, configured to compare corresponding ohmic impedances and charge transfer impedances in the AC impedance spectra of the plurality of cells or the plurality of parallel battery modules to determine the consistency of the battery pack.

Preferably, the processing unit is configured to determine that the consistency of the battery pack is normal when the ohmic impedances and the charge transfer impedances in all AC impedance spectra of the plurality of cells or the plurality of parallel battery modules all satisfy a preset condition, wherein the preset condition is that a difference in the charge transfer impedances is smaller than a first threshold and a difference in the ohmic impedances is smaller than a second threshold under the same AC signal.

Preferably, the processing unit is configured to determine that the consistency of the battery pack is abnormal when the ohmic impedances and the charge transfer impedances in any AC impedance spectrum and other AC impedance spectra of the plurality of cells or the plurality of parallel battery modules do not satisfy a preset condition, wherein the preset condition is that a difference in the charge transfer impedances is smaller than a first threshold and a difference in the ohmic impedances is smaller than a second threshold under the same AC signal.

Preferably, when it is determined that the consistency of the battery pack is abnormal, and the battery pack is a parallel battery pack, the processing unit is configured to determine that a connection point between a cell corresponding to an AC impedance spectrum with a smaller ohmic impedance and the difference greater than the second threshold and a smaller charge transfer impedance and the difference greater than the first threshold compared with other AC impedance spectra, and a cell adjacent to the cell and away from the positive terminal or negative terminal of the battery pack is an abnormal connection point.

According to the above technical solution, the present disclosure provides a method and device for detecting the consistency of a battery pack, which can detect and analyze the consistency of cells and connection points in the battery pack, have the characteristics of no damage and rapidness, and are suitable for detecting the consistency of various electrical connection means such as screw connection and laser soldering.

Other features and advantages of embodiments of the present disclosure will be described in detail in the Detailed Description section that follows.

### BRIEF DESCRIPTION OF FIGURES

The accompanying drawings are included to provide a further understanding of embodiments of the present disclosure and constitute a part of this description, and together with the detailed description below serve to explain, but not limit, embodiments of the present disclosure. In the drawings:

FIG. 1 is a flowchart of a method for detecting the consistency of a battery pack according to an embodiment of the present disclosure;

FIG. 2 is a connection schematic diagram of auxiliary voltage measurements measuring the AC impedance spectrum of a battery pack according to an embodiment of the present disclosure;

FIG. 3 is a schematic diagram of a battery pack composed of two cells connected in parallel according to an embodiment of the present disclosure;

FIG. 4 shows an AC impedance spectrum with normal consistency of a battery pack composed of two cells connected in parallel according to an embodiment of the present disclosure;

FIG. 5 shows an AC impedance spectrum with normal consistency of a battery pack composed of two cells connected in parallel according to another embodiment of the present disclosure;

FIG. 6 shows an AC impedance spectrum with normal consistency of a 3-parallel-3-series (3p3s) battery pack provided by an embodiment of the present disclosure;

FIGS. 7-9 show AC impedance spectra with inconsistent impedances of connection points of a battery pack composed of two cells connected in parallel according to an embodiment of the present disclosure;

FIG. 10 shows an AC impedance spectrum with inconsistent internal resistances of cells in a battery pack composed of two cells connected in parallel according to an embodiment of the present disclosure;

FIG. 11a is a schematic diagram of an electrode connection method in a series-connection measurement mode during electrochemical impedance spectroscopy (EIS) using an electrochemical workstation according to an embodiment of the present disclosure;

FIG. 11b is a schematic diagram of an electrode connection method in a parallel-connection measurement mode during electrochemical impedance spectroscopy (EIS) using an electrochemical workstation according to an embodiment of the present disclosure;

FIG. 12 is a schematic diagram of an AC impedance spectrum with inconsistent impedances of connection points of a 3p3s battery pack according to an embodiment of the present disclosure; and

FIG. 13 is a structural block diagram of a device for detecting the consistency of a battery pack according to an embodiment of the present disclosure.

### DESCRIPTION OF REFERENCE NUMERALS

1 Detection unit 2 Processing unit

### DETAILED DESCRIPTION

Specific embodiments of the present disclosure will now be described with reference to the accompanying drawings. It should be understood that the specific embodiments described here are only used to illustrate and explain the embodiments of the present disclosure, and are not intended to limit the embodiments of the present disclosure.

In the present disclosure, the problems of unreliable connection such as loose screws and unreliable soldering during the connection of power batteries are referred to as “cold solder joint”. The cold solder joints in the battery pack all have the characteristics of having resistances greater than the resistances of other normal connection points. In a parallel battery pack, the cell voltages are the same, but the currents passing through each cell may differ due to the different internal resistances of the cells or different resistances of the parallel connection points, and the current tends to selectively flow through paths with lower resistances so that the current passing through each cell is different, thereby reducing the cycle life of the battery pack.

With the technical solution of the present disclosure, it is possible to examine the virtual solder joint of the parallel circuit without performing charge-discharge test on the battery pack, which is within the scope of non-destructive testing technology. Of course, the technical solution of the present disclosure is equally effective for cold solder detection in series circuits. At the same time, the cells used to assemble the battery pack are subjected to AC impedance spectrum measurement before grouping, and the curves of the AC impedance spectra of the cells that enter the grouping process after being sorted by parameters such as internal resistance, capacity and voltage all coincide with each other, indicating that the consistency among the cells is very good.

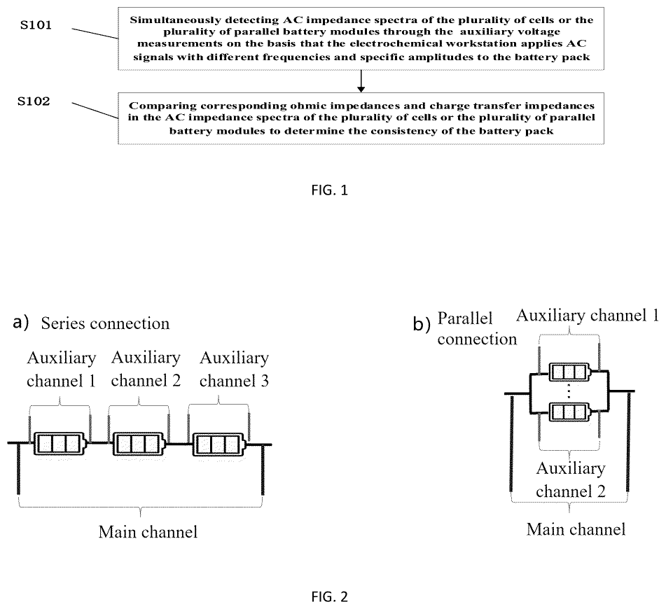

FIG. 1 is a flowchart of a method for detecting the consistency of a battery pack according to an embodiment of the present disclosure. As shown in FIG. 1, the battery pack includes a plurality of cells or a plurality of parallel battery modules, wherein connection points are arranged among the plurality of cells or the plurality of parallel battery modules, and the method is based on an electrochemical workstation with auxiliary voltage measurements, and includes:

Step S101, simultaneously detecting AC impedance spectra of the plurality of cells or the plurality of parallel battery modules through the auxiliary voltage measurements on the basis that the electrochemical workstation applies AC signals with different frequencies and specific amplitudes to the battery pack;

wherein the electrochemical workstation with auxiliary voltage measurements used in embodiments of the present disclosure is preferably a Solartron Echemlab XM type electrochemical workstation, equipped with a 100 V voltage module and standard 4 auxiliary voltage measurements, a main channel of the electrochemical station with auxiliary voltage measurements is configured to apply AC signals with different frequencies and specific amplitudes to the battery pack to measure the change of the ratio of voltage to current of the AC signal (the ratio is the impedance of the battery pack) with the sine wave frequency, or the change of the phase angle of the impedance with the sine wave frequency; the auxiliary voltage measurements are configured to measure, after AC signals with different frequencies and specific amplitudes are applied to the battery pack, the change in the instantaneous impedance of the cells or the plurality of parallel battery modules forming the battery pack with the sine wave frequency, or the change in the phase angle of the instantaneous impedance of the cells or the plurality of parallel battery modules with the sine wave frequency. The electrochemical workstation with the auxiliary voltage measurements enables simultaneous in-situ measurement of the AC impedance spectrum of the battery pack and the cells or the plurality of parallel battery modules in the battery pack under the same AC signal.

FIG. 2 is a connection schematic diagram of the electrochemical workstation with the auxiliary voltage measurements measuring the AC impedance spectrum of a battery pack. From the connection of the battery pack to the test equipment, and taking a series battery pack as an example, the main impedance channel of the electrochemical workstation is connected to the positive and negative terminals of the battery pack to measure the AC impedance spectrum of the whole battery pack, and the auxiliary voltage measurement channel of the electrochemical workstation is connected to the positive and negative terminals of a cell or parallel battery module in the battery pack to measure the AC impedance spectrum of each cell or battery module under the same AC signal. Step S102, comparing corresponding ohmic impedances and charge transfer impedances in the AC impedance spectra of the plurality of cells or the plurality of parallel battery modules to determine the consistency of the battery pack.

The present disclosure is exemplified below by choosing a square aluminum shell lithium iron phosphate battery with a nominal capacity of 30 Ah. The aluminum tabs are soldered to the poles of the cells by laser soldering, and then the cell tabs are connected by SUS304 stainless steel screws to realize the series-parallel connection of the cells. The cold solder points are realized by controlling the tightness of the connection screws, that is, the screws at normal connection points are tightened by a wrench, while the cold solder points are designed to not tighten the connection screws. In the embodiment of the present disclosure, the test conditions of the AC impedance spectrum of the 2-parallel 60 Ah battery pack are that the frequency range is 2000 Hz-0.01 Hz, and the current amplitude is 200 mA; the test conditions of the AC impedance spectrum of a 3p3s battery pack are that the frequency range is 2000 Hz-0.01 Hz, and the current amplitude is 3000 mA.

Specifically, when the ohmic impedances and the charge transfer impedances in all the AC impedance spectra of the plurality of cells or the plurality of parallel battery modules satisfy a preset condition, it is determined that the consistency of the battery pack is normal, wherein the preset condition is that the differences in the charge transfer impedances is smaller than a first threshold and the difference in the ohmic impedances is smaller than a second threshold under the same AC signal. The following is an example of a case where the consistency of the battery pack is normal:

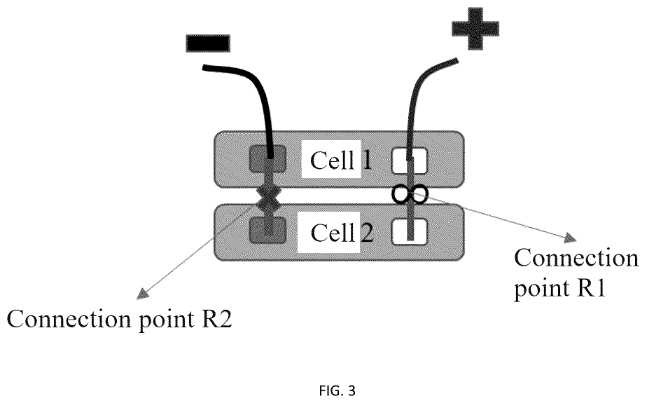

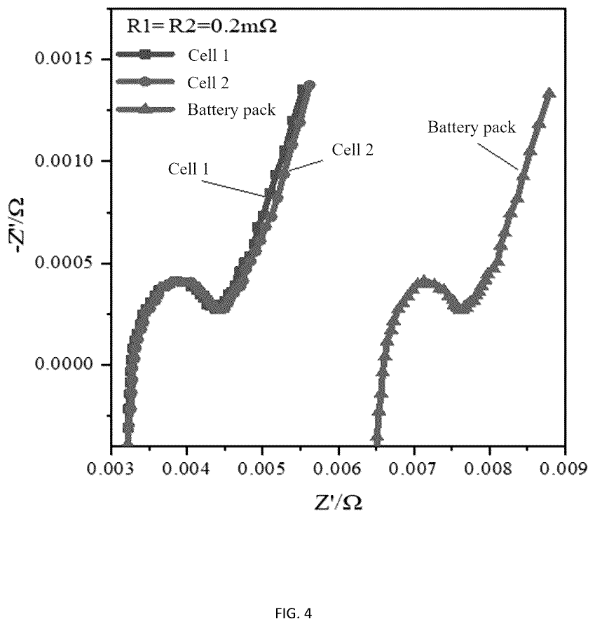

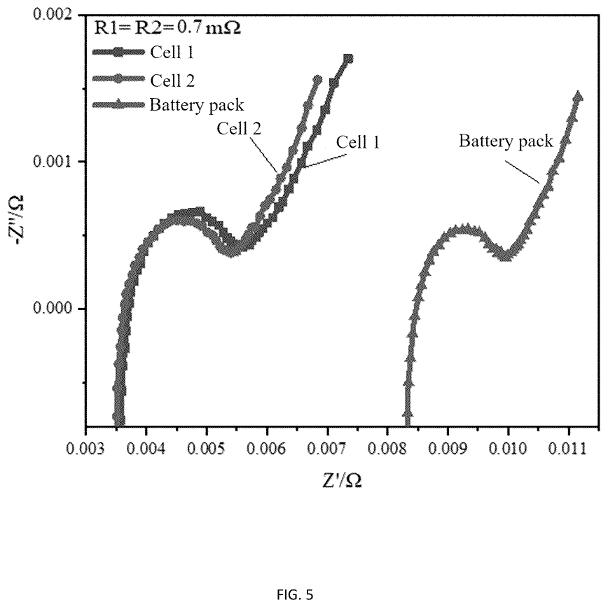

FIG. 3 is a schematic diagram of a battery pack composed of two cells connected in parallel according to an embodiment of the present disclosure. As shown in FIG. 3, the normal resistances of two connection points of positive and negative electrodes are R1=R2=0.2 mΩ, the AC impedance spectra of the battery pack and the cells at this time are shown in FIG. 4, the AC impedance spectra of the two cells overlap with each other (the difference in the charge transfer impedances is smaller than a first threshold and the difference in the ohmic impedances is smaller than a second threshold under the same AC signal, and the values of the first and second thresholds may depend on the battery pack consistency requirements, the same below), indicating that the consistency of the connection points of the battery pack is normal. Of course, if the normal resistances of the two connection points of the positive and negative electrodes are large, such as R1=R2=0.7 mΩ, then the AC impedance spectra of the battery pack and the cells are shown in FIG. 5, which also indicates that the consistency of the connection points of the battery pack are good, but the ohmic impedance (0.83 mΩ) of the battery pack at this time is obviously greater than that of the normally connected battery pack (0.66 mΩ).

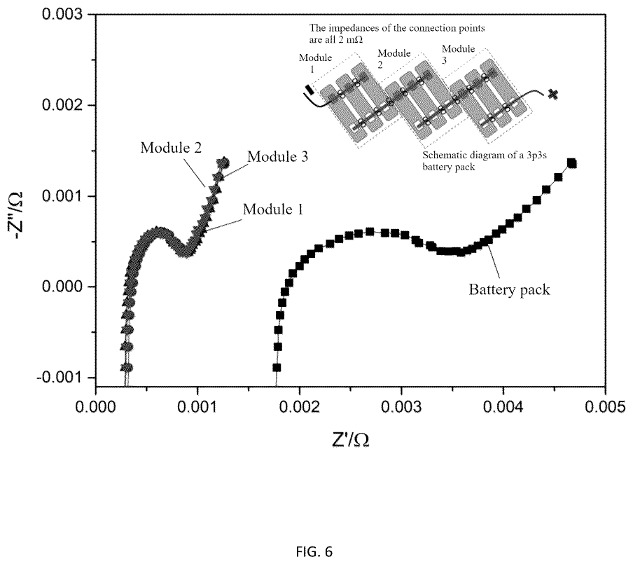

FIG. 6 is a schematic diagram of an AC impedance spectrum with normal consistency of a 3p3s battery pack provided by an embodiment of the present disclosure. As shown in FIG. 6, the resistances of all connection points in the 3p3s battery pack are 0.2 mΩ, and the AC impedance spectra of the cells after sorting are equivalent, and the AC impedance spectra of the three parallel battery modules also overlap one another in the whole battery pack, showing high consistency.

It should be noted that the ohmic impedance data in FIG. 6 are all measured from the 3p3s battery pack. During the measurement, the working electrode and reference electrode of the main channel of the electrochemical workstation are connected to the positive terminal and negative terminal of the battery pack respectively, and the working electrodes and reference electrodes of the three auxiliary channels are connected to the positive terminal and negative terminal of the parallel battery module respectively. There is no series connection mode between the working electrode of the main channel and the working electrode of the auxiliary channel, so the measured ohmic impedance of the battery is the real-time ohmic impedance of the 3p3s battery pack and its 3p battery module.

Further, when the ohmic impedances and the charge transfer impedances in any AC impedance spectrum and other AC impedance spectra of the plurality of cells or the plurality of parallel battery modules do not meet a preset condition, it is determined that the consistency of the battery pack is abnormal, wherein the preset condition is that the difference in the charge transfer impedances is smaller than a first threshold and the difference in the ohmic impedances is smaller than a second threshold under the same AC signal. The following is an example of a case where the consistency of the battery pack is abnormal:

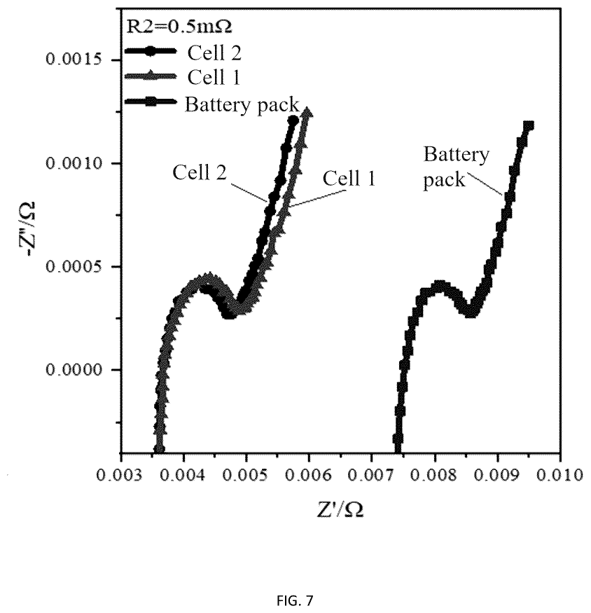

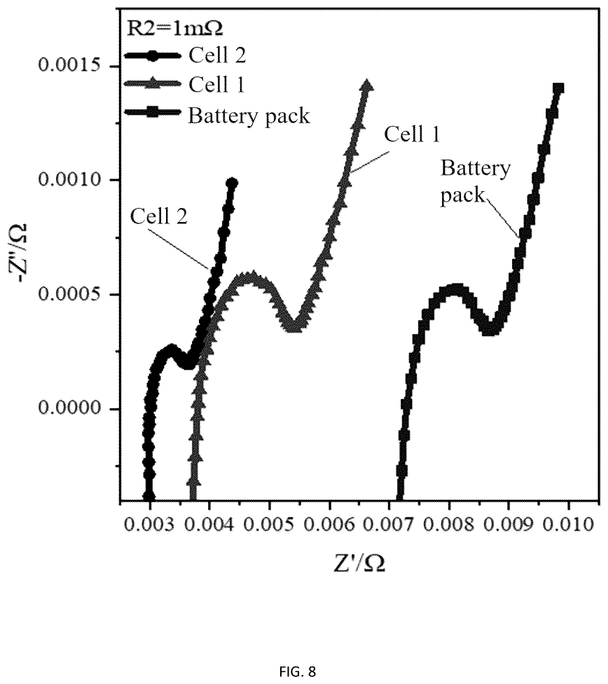

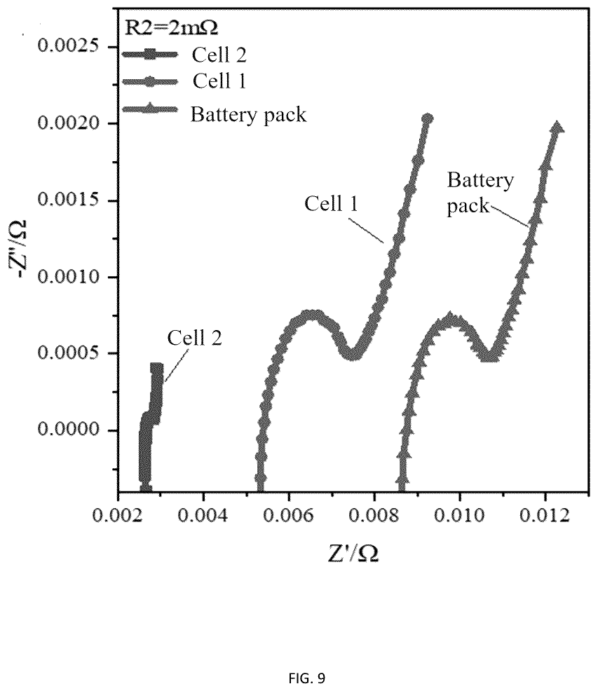

FIGS. 7-9 are schematic diagrams of AC impedance spectra with inconsistent impedances of the connection points of a battery pack composed of two cells connected in parallel according to an embodiment of the present disclosure. As shown in FIGS. 7-9, when one of the impedances of the connection points of the positive and negative electrodes is greater than the other, the position and shape of the AC impedance spectrum curve of the parallel cells will deviate, and the AC impedance spectrum of the cell with smaller current will move toward the direction of smaller ohmic impedance, and the charge transfer impedance will also decrease with the increase of the impedance value of a connection point.

By adjusting the resistance R2 of the connection point of the negative electrode, it can be found that with the increase of the resistance R2, the current passing through Cell 2 will be smaller during the charging and discharging process. Therefore, in the comparison of the in-situ AC impedance spectrum, Cell 2 first shows a trend that the charge transfer impedance becomes smaller (for example, when R2=0.5 mΩ), and then the charge transfer impedance and the ohmic impedance become smaller at the same time (for example, when R2=2 m (2). At the same time, Cell 1 shows a slight increase in the ohmic impedance, so that the AC impedance spectra of the two cells are severely misaligned. As the impedance of the connection point of the negative electrode increases from 0.2 mΩ to 2 mΩ, the ohmic impedance of the battery pack, as indicated by the AC impedance, increases significantly from 0.66 mΩ to 0.84 mΩ.

Based on this, it can be concluded that in a parallel battery module, a connection point between a cell corresponding to an AC impedance spectrum with a greater ohmic impedance and the difference greater than the second threshold and the difference in the charge transfer impedances smaller than the first threshold, and a cell adjacent to the cell and away from the positive or negative terminal of the battery pack is an abnormal connection point.

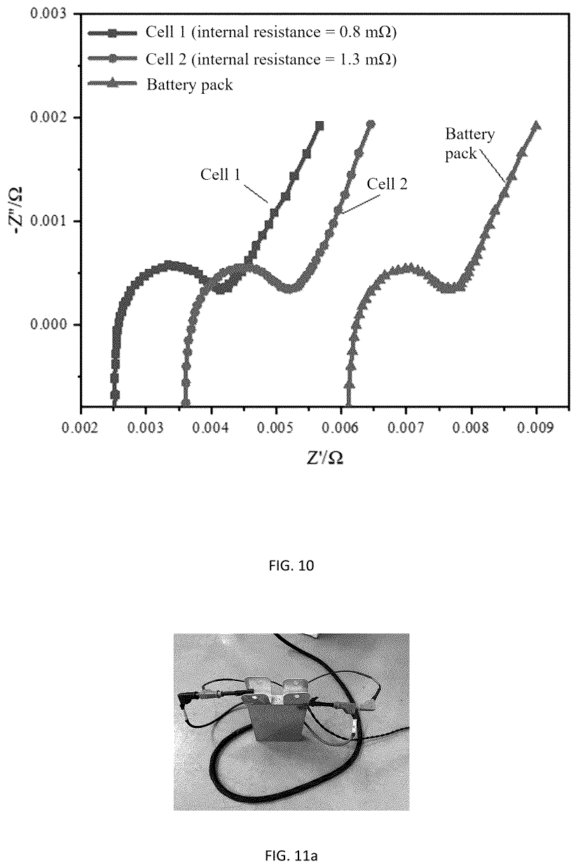

FIG. 10 is a schematic diagram of an AC impedance spectrum with inconsistent internal resistances of cells of a battery pack composed of two cells connected in parallel according to an embodiment of the present disclosure. As shown in FIG. 10, after two cells with different internal resistances are connected in parallel, the electrical connection impedances of the positive and negative electrodes are both normal connection points (0.2 m (2). At this time, the cells with different internal resistances exhibit differences in ohmic impedance in the battery pack, the cell with large resistance exhibits a greater ohmic impedance. The difference from the change trend of AC impedance spectrum caused by the cold solder of one connection point is that the charge transfer impedances of the two cells with different internal resistances in the in-situ AC impedance spectrum are still similar.

Based on this, it can be concluded that a cell corresponding to an AC impedance spectrum with a greater ohmic impedance and the difference greater than the second threshold and the difference in the charge transfer impedances smaller than the first threshold is an abnormal cell.

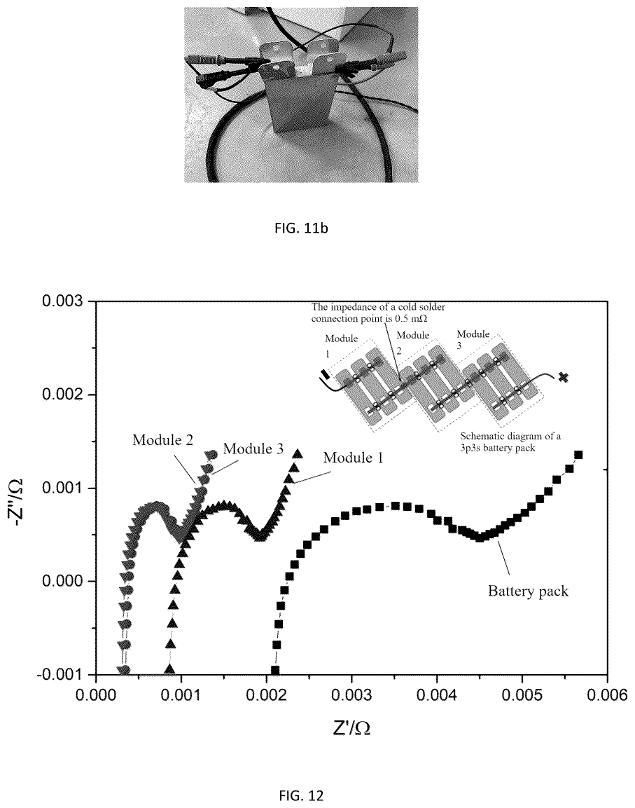

It should be noted that the ohmic impedance data in FIG. 4, FIG. 5 and FIGS. 7-10 are all measured from the parallel battery module. During the measurement, the electrode connection method of the electrochemical workstation adopts the series connection mode of the working electrode of the main channel and the working electrode of the auxiliary channel (see FIG. 11a), resulting in the measured and displayed ohmic impedance of the battery being ten times the actual value. Nevertheless, the two measurement connection methods have no effect on the electrochemical transfer impedance of the battery.

FIG. 12 is a schematic diagram of an AC impedance spectrum with inconsistent impedances of connection points of a 3p3s battery pack according to an embodiment of the present disclosure. As shown in FIG. 12, if one of the two series connection points of the 3p3s battery pack is increased to 0.5 mΩ, as a result, during in-situ AC impedance spectrum detection, the ohmic impedance of Module 1 in the AC impedance spectrum is obviously greater than the ohmic impedances of Modules 2 and 3, and the ohmic impedance and charge transfer impedance of the whole battery pack are obviously greater than that of the battery pack with normal connection points. When the battery pack is a cell-series battery pack, the determination can likewise be made in turn. That is, if there is a connection point inconsistency on the series circuit, the parallel battery module or cell between the connection point with greater resistance and the positive or negative terminal, closest to the connection point, of the series battery pack exhibits a greater ohmic impedance characteristic, while the ohmic impedance and charge transfer impedance of the entire series battery pack are greater than those of the normally connected battery pack.

Based on this, it can be concluded that which specific connection point on the series circuit of the battery pack is abnormal, that is, it is determined that a connection point between a cell or parallel battery module corresponding to an AC impedance spectrum with a greater ohmic impedance and the difference greater than the second threshold and the difference in the charge transfer impedances smaller than the first threshold compared with other AC impedance spectra, and a cell or parallel battery module adjacent to the cell or parallel battery module and away from the positive or negative terminal of the battery pack is an abnormal connection point.

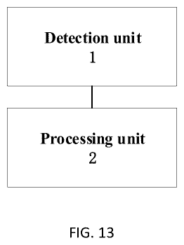

FIG. 13 is a structural block diagram of a device for detecting the consistency of a battery pack according to an embodiment of the present disclosure. As shown in FIG. 13, the battery pack includes a plurality of cells or a plurality of parallel battery modules, wherein connection points are arranged among the plurality of cells or the plurality of parallel battery modules. The device is based on an electrochemical workstation with auxiliary voltage measurements, and includes a processor, wherein the processor is configured to execute the following program modules stored in a memory: a detection unit 1, configured to simultaneously detect AC impedance spectra of the plurality of cells or the plurality of parallel battery modules through the auxiliary voltage measurements on the basis that the electrochemical workstation applies AC signals with different frequencies and specific amplitudes to the battery pack; and a processing unit 2, configured to compare corresponding ohmic impedances and charge transfer impedances in the AC impedance spectra of the plurality of cells or the plurality of parallel battery modules to determine the consistency of the battery pack.

Preferably, the processing unit 2 is configured to determine that the consistency of the battery pack is normal when the ohmic impedances and the charge transfer impedances in all AC impedance spectra of the plurality of cells or the plurality of parallel battery modules all satisfy a preset condition, wherein the preset condition is that the difference in the charge transfer impedances is smaller than a first threshold and the difference in the ohmic impedances is smaller than a second threshold under the same AC signal.

Preferably, the processing unit 2 is configured to determine that the consistency of the battery pack is abnormal when the ohmic impedances and the charge transfer impedances in any AC impedance spectrum and other AC impedance spectra of the plurality of cells or the plurality of parallel battery modules do not satisfy a preset condition, wherein the preset condition is that the difference in the charge transfer impedances is smaller than a first threshold and the difference in the ohmic impedances is smaller than a second threshold under the same AC signal.

Preferably, when it is determined that the consistency of the battery pack is abnormal, and the battery pack is a parallel battery pack, the processing unit 2 is configured to determine that a connection point between a cell corresponding to an AC impedance spectrum with a smaller ohmic impedance and the difference greater than the second threshold and the difference in the charge transfer impedances smaller than the first threshold compared with other AC impedance spectra, and a cell or parallel battery module adjacent to the cell and away from the positive or negative terminal of the battery pack is an abnormal connection point.

The embodiment of the device for detecting the consistency of the battery pack described above is similar to the embodiment of the method for detecting the consistency of the battery pack described above, and will not be described in detail herein.

It should be understood by those skilled in the art that modules or steps of the present disclosure may be implemented by a general computing device, which may be centralized on a single computing device or distributed over a network composed of a plurality of computing devices. Alternatively, the modules or steps may be implemented by program codes executable by the computing devices, so that the modules or steps can be stored in a storage device to be executed by the computing device, and in some cases, the steps shown or described may be performed in a different order from here, or the modules or steps may be respectively made into various integrated circuit modules, or multiple modules or steps among them may be made into a single integrated circuit module. As such, the present disclosure is not limited to any specific combination of hardware and software.

As will be appreciated by those skilled in the art, embodiments of the present disclosure may be provided as a method, a system, or a computer program product. Accordingly, the present application may take the form of an entirely hardware embodiment, an entirely software embodiment or an embodiment combining software and hardware aspects. Furthermore, the present application may take the form of a computer program product implemented on one or more computer-usable storage media (including but not limited to disk storage, CD-ROM, optical storage, etc.) containing computer-usable program codes.

The present application is described with reference to flowcharts and/or block diagrams of methods, devices (systems), and computer program products according to embodiments of the present application. It should be understood that each flow and/or block in the flowcharts and/or block diagrams, and combinations of flows and/or blocks in the flowcharts and/or block diagrams can be implemented by computer program instructions. These computer program instructions may be provided to a processor of a general purpose computer, special purpose computer, embedded processor, or other programmable data processing device to produce a machine, such that the instructions, which are executed by the processor of the computer or other programmable data processing devices, produce devices for implementing the functions specified in one flow or multiple flows of the flowchart and/or one block or multiple blocks in the block diagram.

These computer program instructions may also be stored in a computer-readable memory that can direct a computer or other programmable data processing devices to function in a particular manner, such that the instructions stored in the computer-readable memory produce an article of manufacture including instruction devices which implement the functions specified in one flow or multiple flows of the flowchart and/or one block or multiple blocks in the block diagram.

These computer program instructions may also be loaded onto a computer or other programmable data processing devices, such that a series of operational steps are performed on a computer or other programmable devices to produce computer-implemented processing such that the instructions, which are executed on the computer or other programmable devices provide steps for implementing the functions specified in one flow or multiple flows of the flowchart and/or one block or multiple blocks in the block diagram.

In one typical configuration, a computing device includes one or more processors (CPU), an input/output interface, a network interface, and a memory.

The memory may include volatile memory, random access memory (RAM) and/or non-volatile memory in computer-readable media, such as read-only memory (ROM) or flash RAM. The memory is an example of a computer-readable medium.

The computer-readable media includes permanent and non-permanent, and removable and non-removable media that can realize information storage in any method or technology. The information may be computer-readable instructions, data structures, modules of a program, or other data. Examples of storage media of a computer include, but not limited to phase change memory (PRAM), static random access memory (SRAM), dynamic random access memory (DRAM), other types of random access memory (RAM), read only memory (ROM), electrically erasable programmable read only memory (EEPROM), flash memory or other memory technology, compact disc read only memory (CD-ROM), digital versatile disc (DVD) or other optical storage, magnetic cassettes, magneto-magnetic disk storage or other magnetic storage devices, or any other non-transmission medium that can be used to store information that can be accessed by a computing device. As defined herein, the computer-readable media does not include transitory computer-readable media, such as modulated data signals and carrier waves.

It also needs to be noted that, the terms “includes,” “including,” or any other variation thereof, are intended to cover a non-exclusive inclusion, such that a process, method, article, or device that includes a list of elements does not include only those elements but may include other elements not expressly listed or inherent to such process, method, article, or device. Without more restrictions, the element defined by the sentence “including a . . . ” does not exclude that there are other identical elements in the process, method, article, or device including the element.

The above are only embodiments of the present application, and are not intended to limit the present application. Various modifications and variations may be made to the present disclosure by those skilled in the art. All such modifications, equivalents, improvements, and the like within the spirit and principles of the present application should be included within the scope of the claims of the present application.

1. A method for detecting the consistency of a battery pack, wherein the battery pack comprises a plurality of cells or a plurality of parallel battery modules, connection points are arranged among the plurality of cells or the plurality of parallel battery modules, and the method is based on an electrochemical workstation with auxiliary voltage measurements, and comprises the following steps:
detecting alternating current (AC) impedance spectra of the plurality of cells or the plurality of parallel battery modules simultaneously through the auxiliary voltage measurements on the basis that the electrochemical workstation applies AC signals with different frequencies and specific amplitudes to the battery pack; and
comparing corresponding ohmic impedances and charge transfer impedances in the AC impedance spectra of the plurality of cells or the plurality of parallel battery modules to determine the consistency of the battery pack.

2. The method for detecting the consistency of a battery pack according to claim 1, wherein comparing corresponding ohmic impedances and charge transfer impedances in the AC impedance spectra of the plurality of cells or the plurality of parallel battery modules to determine the consistency of the battery pack comprises:
determining that the consistency of the battery pack is normal when the ohmic impedances and the charge transfer impedances in all AC impedance spectra of the plurality of cells or the plurality of parallel battery modules all satisfy a preset condition, wherein the preset condition is that a difference in the charge transfer impedances is smaller than a first threshold and a difference in the ohmic impedances is smaller than a second threshold under the same AC signal.

3. The method for detecting the consistency of a battery pack according to claim 1, wherein comparing corresponding ohmic impedances and charge transfer impedances in the AC impedance spectra of the plurality of cells or the plurality of parallel battery modules to determine the consistency of the battery pack comprises:
determining that the consistency of the battery pack is abnormal when the ohmic impedances and the charge transfer impedances in any AC impedance spectrum and other AC impedance spectra of the plurality of cells or the plurality of parallel battery modules do not satisfy a preset condition, wherein the preset condition is that a difference in the charge transfer impedances is smaller than a first threshold and a difference in the ohmic impedances is smaller than a second threshold under the same AC signal.

4. The method for detecting the consistency of a battery pack according to claim 3, wherein when it is determined that the consistency of the battery pack is abnormal, and the battery pack is a parallel battery pack, the method further comprises:
determining that a cell corresponding to an AC impedance spectrum with a greater ohmic impedance and the difference greater than the second threshold and the difference in the charge transfer impedances smaller than the first threshold compared with other AC impedance spectra is an abnormal cell.

5. The method for detecting the consistency of a battery pack according to claim 3, wherein when it is determined that the consistency of the battery pack is abnormal, and the battery pack is a parallel battery pack, the method further comprises:
determining that a connection point between a cell corresponding to an AC impedance spectrum with a smaller ohmic impedance and the difference greater than the second threshold and a smaller charge transfer impedance and the difference greater than the first threshold compared with other AC impedance spectra, and a cell adjacent to the cell and away from the positive terminal or negative terminal of the battery pack is an abnormal connection point.

6. The method for detecting the consistency of a battery pack according to claim 3, wherein when it is determined that the consistency of the battery pack is abnormal, and the battery pack is a series battery pack or a plurality of parallel battery modules connected in series, the method further comprises:
determining that a connection point between a cell or parallel battery module corresponding to an AC impedance spectrum with a greater ohmic impedance and the difference greater than the second threshold and the difference in the charge transfer impedances smaller than the first threshold compared with other AC impedance spectra, and a cell or parallel battery module adjacent to the cell or parallel battery module and away from the positive terminal or negative terminal of the battery pack is an abnormal connection point.

7. A device for detecting the consistency of a battery pack, wherein the battery pack comprises a plurality of cells or a plurality of parallel battery modules, connection points are arranged among the plurality of cells or the plurality of parallel battery modules, and the device is based on an electrochemical workstation with auxiliary voltage measurements, and comprises a processor, wherein the processor is configured to execute the following program modules stored in a memory:
a detection unit, configured to simultaneously detect AC impedance spectra of the plurality of cells or the plurality of parallel battery modules through the auxiliary voltage measurements on the basis that the electrochemical workstation applies AC signals with different frequencies and specific amplitudes to the battery pack; and
a processing unit, configured to compare corresponding ohmic impedances and charge transfer impedances in the AC impedance spectra of the plurality of cells or the plurality of parallel battery modules to determine the consistency of the battery pack.

8. The device for detecting the consistency of a battery pack according to claim 7, wherein the processing unit is configured to:
determine that the consistency of the battery pack is normal when the ohmic impedances and the charge transfer impedances in all AC impedance spectra of the plurality of cells or the plurality of parallel battery modules all satisfy a preset condition, wherein the preset condition is that a difference in the charge transfer impedances is smaller than a first threshold, and a difference in the ohmic impedances is smaller than a second threshold under the same AC signal.

9. The device for detecting the consistency of a battery pack according to claim 7, wherein the processing unit is configured to:
determine that the consistency of the battery pack is abnormal when the ohmic impedances and the charge transfer impedances in any AC impedance spectrum and other AC impedance spectra of the plurality of cells or the plurality of parallel battery modules do not satisfy a preset condition, wherein the preset condition is that a difference in the charge transfer impedances is smaller than a first threshold and a difference in the ohmic impedances is smaller than a second threshold under the same AC signal.

10. The device for detecting the consistency of a battery pack according to claim 9, wherein when it is determined that the consistency of the battery pack is abnormal, and the battery pack is a parallel battery pack, the processing unit is configured to:
determine that a connection point between a cell corresponding to an AC impedance spectrum with a smaller ohmic impedance and the difference greater than the second threshold and a smaller charge transfer impedance and the difference greater than the first threshold compared with other AC impedance spectra, and a cell adjacent to the cell and away from the positive terminal or negative terminal of the battery pack is an abnormal connection point.
